(19) United States
(12) Patent Application Publication
(10) Pub. No.: US 2011/0210323 A1
(43) Pub. Date: Sep. 1, 2011

(54) ORGANIC ELECTROLUMINESCENT ELEMENT AND DISPLAY DEVICE

(75) Inventor: Toshiaki Imai, Kanagawa (JP)

(73) Assignee: SONY CORPORATION, Tokyo (JP)

(21) Appl. No.: 13/124,424

(22) PCT Filed: Nov. 13, 2009
(86) PCT No.: PCT/JP2009/069338

§ 371 Date: Apr. 15, 2011

(30) Foreign Application Priority Data
Nov. 19, 2008 (JP) 2008-295118

(51) Int. Cl. H01L 51/54

(52) U.S. Cl. 257/40; 257/E51.024

(57) ABSTRACT

An organic electroluminescent element, in which reduction in drive voltage is achieved, is provided. The organic electroluminescent element has an organic layer 20 between an anode 11 and a cathode 31, and the organic layer 20 has a structure where an n-doped layer 21, a hole transport layer 22, a light emitting layer 23, and an electron transport layer 24 are stacked in order from an anode 11 side. The n-doped layer 21 contains hexacyanohexaazatriphenylene and 4,4′,4″-tris(3-methylphenylphenylamino)triphenylamine. When an electric field is applied to the organic layer 20, holes from the anode 11 are efficiently sufficiently injected into the light emitting layer 23.

### TECHNICAL FIELD

The present invention relates to an organic electroluminescent element used for a color display or the like and a display device using the organic electroluminescent element.

### BACKGROUND ART

Recently, a flat display has been actively researched and developed as an alternative display device to a Cathode-ray tube (CRT) since the flat display is light in weight and low in power consumption. In particular, attention is focused on a display device using an organic electroluminescent element as a self-luminous display element (so-called light emitting element).

The organic electroluminescent element used for the display device is classified into, for example, a bottom emission type and a top emission type depending on an extraction direction of emission light. As the bottom emission type, an organic electroluminescent element is known, which is configured to have an anode including a transparent electrode material such as ITO (Indium Tin Oxide) on a transparent substrate such as glass substrate, an organic layer on the anode, and a cathode on a top of the organic layer. The organic layer is configured such that, for example, a hole transport layer, a light emitting layer, and an electron transport layer are sequentially stacked from an anode side. In the organic electroluminescent element, light, which is generated in the light emitting layer when electrons injected from the cathode are recombined with holes injected from the anode, is extracted from a substrate side (bottom side).

On the other hand, as the top emission type, an organic electroluminescent element, which is configured such that a cathode, an organic layer and an anode are sequentially stacked from a substrate side with the same materials as those used for the bottom-emission-type organic electroluminescent element, or an organic electroluminescent element, which has an electrode on an upper side (upper electrode) including a transparent or semi-transmitting electrode material are included. In this case, light is extracted from a side opposite to a substrate side. When the top-emission-type organic electroluminescent element is used for an active-matrix display device having driver circuits including thin film transistors (TFT) on a substrate, the organic electroluminescent element is advantageous in increase in aperture ratio of a light emitting region since light is extracted without being interfered by the driver circuits.

In such a top emission type, an electrode on a substrate side may be formed of a highly light-reflective metal film, which may be used as the anode. Aluminum or silver is used as a material forming the metal film. However, when the metal film including aluminum or the like is used as the anode, since the metal film has a low work function, holes are hardly directly injected from the anode into the organic layer. This leads to hole deficiency, causing tendency to increase in drive voltage and reduction in luminous efficiency, which is a shortcoming Thus, a technique has been proposed, in which a layer including a hexaazatriphenylene derivative is provided on the anode to promote hole injection into the organic layer (see patent document 1).

Moreover, a technique is proposed, in which when an anode is formed of a material having a high work function such as ITO, a p-doped layer is provided on the anode to suppress increase in drive voltage (see non-patent document 1). The p-doped layer is formed of a material including a p-type host compound doped with a p-type dopant compound. As the p-type host compound and the p-type dopant compound, 4,4′,4″-tris(3-methylphenylphenylamino)triphenylamine and 2,3,5,6-tetra-fluoro-7,7,8,8-tetracyanoquinodimethane are used, respectively.

### CITATION LIST

### Patent Document

Patent document 1: Japanese Unexamined Patent Application Publication (Translation of PCT Application) No. 2006-503443.
Non-patent document 1: Jingsong Huang and five others “Low-voltage organic electroluminescent devices using pin structures”, APPLIED PHYSICS LETTERS, Jan. 7, 2002, 80, 1, pp. 139-141.

### SUMMARY OF THE INVENTION

However, the techniques of the patent document 1 and the non-patent document 1 do not sufficiently reduce drive voltage of an organic electroluminescent element, leading to a demand for a technique for achieving more reduction in drive voltage.

The invention has been made in the light of such a shortcoming, and an object of the invention is to provide an organic electroluminescent element and a display device, in which reduction in drive voltage is achieved.

An organic electroluminescent element according to an embodiment of the invention includes an organic layer including a light emitting layer between an anode and a cathode, in which the organic layer has an n-doped layer, including an n-type host compound and an n-type dopant compound, between the anode and the light emitting layer. Furthermore, a display device according to an embodiment of the invention includes the above-mentioned organic electroluminescent element of the embodiment. “N-doped” means that a host and a dopant doped into the host are in a relationship where an absolute value of highest occupied molecular orbital (HOMO) energy of a dopant molecule is higher than an absolute value of lowest unoccupied molecular orbital (LUMO) energy of a host molecule. That is, (absolute value of HOMO energy of dopant molecule)>(absolute value of LUMO energy of host molecule) is satisfied in the relationship. In addition, “n-doped layer” refers to a layer including an n-type host compound as the host and an n-type dopant compound as the dopant, the host and dopant compounds satisfying the above n-doped relationship.

In the organic electroluminescent element and the display device according to the embodiments of the invention, the absolute value of HOMO energy of the n-type dopant compound is higher than the absolute value of LUMO energy of the n-type host compound in the n-doped layer between the anode and the light emitting layer. Therefore, while an electric field is not applied or is applied between the electrodes, electrons are easily extracted from HOMO of the n-type dopant compound to LUMO of the n-type host compound. Accordingly, the n-type dopant compound is positively charged and the n-type host compound becomes an electron path, so that negative space charge of the n-type host compound is relaxed, leading to reduction in resistance of the n-doped layer during charge transfer. In addition to this electron concentration that may concern charge transfer is increased, which facilitates charge transfer. Therefore, when an electric field is applied between the electrodes, increase in voltage applied on the organic layer is suppressed, and thus holes, which are efficiently transferred from an anode side via the n-doped layer, and electrons, which are efficiently transferred from a cathode side, are recombined in the light emitting layer, leading to light emission.

According to the organic electroluminescent element and the display device of the embodiments of the invention, since the n-doped layer including the n-type host compound and the n-type dopant compound are provided between the anode and the light emitting layer, drive voltage is allowed to be reduced.

### BRIEF DESCRIPTION OF THE DRAWINGS

FIG. 1 A section diagram showing a configuration of an organic electroluminescent element according to a first embodiment of the invention.

FIG. 2 A diagram for illustrating charge transfer between an anode and an n-doped layer.

FIG. 3 A diagram for illustrating charge transfer between the anode and a p-doped layer.

FIG. 4 A section diagram showing a configuration of a display device having the organic electroluminescent element.

FIG. 5 A section diagram showing a wiring structure according to a second embodiment of the invention.

FIG. 6 A graph showing a relationship between voltage and current in experimental examples.

### DESCRIPTION OF EMBODIMENTS

Hereinafter, embodiments of the invention will be described in detail with reference to drawings. Description is made in the following sequence.

1. First embodiment
(1-1) Organic electroluminescent element (example of top emission type)
(1-2) Display device (usage example of the organic electroluminescent element)
2. Second embodiment (wiring material)

### 1. First Embodiment

### [(1-1) Organic Electroluminescent Element (Example of Top Emission Type)]

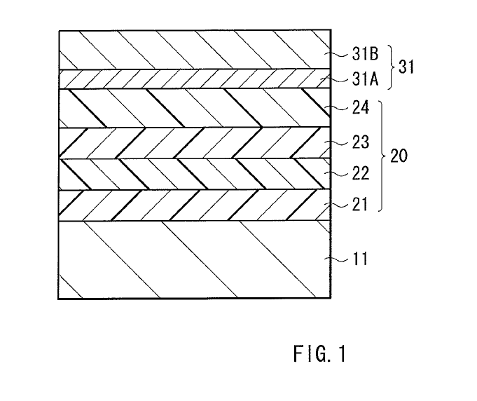

FIG. 1 shows a sectional configuration of an organic electroluminescent element according to a first embodiment of the invention. The organic electroluminescent element (organic EL element) is used for a display device such as a color display. The organic electroluminescent element has an organic layer 20 between an anode 11 and a cathode 31. The organic layer 20 has a structure where an n-doped layer 21, a hole transport layer 22, a light emitting layer 23 and an electron transport layer 24 are stacked in order from an anode 11 side. Here, description is made on a top-emission-type organic electroluminescent element where light emitted from the light emitting layer 23 (hereinafter, called emission light) is extracted from a cathode 31 side.

The anode 11 is provided on a substrate such as a transparent substrate including glass, a silicon substrate, or a film-shaped flexible substrate. When a display device including the organic electroluminescent element is driven by an active matrix method, the anode 11 is formed in a matrix for each of pixels on a substrate having driver circuits such as TFT for each of pixels.

The anode 11 is preferably formed such that the anode may reflect substantially all wavelength components of visible light. As a material forming the anode 11, for example, a conductive material having a work function of 4.5 eV or less is preferable. This is because the anode 11 formed of such a material is increased in reflectance of visible light, and obtains high luminous efficiency. Examples of such a material include the following: aluminum, nickel, silver, gold, platinum, palladium, selenium, rhodium, ruthenium, iridium, rhenium, tungsten, molybdenum, chromium, tantalum and niobium, or an alloy containing one or two or more of the metals, or an oxide of each metal or alloy. In addition, tin oxide, ITO, zinc oxide and titanium oxide are cited. The materials may be singly used, or may be used in a combined manner. In particular, the anode 11 preferably contains aluminum, and is more preferably an alloy containing aluminum as a major component and an element having a relatively low work function compared with aluminum, as a sub component (hereinafter, called aluminum alloy). This is because such an alloy has high reflectance and is relatively inexpensive. The sub component in the aluminum alloy is preferably a lanthanoid series element. The lanthanoid series element does not have a high work function. However, when the alloy contains the lanthanoid series element, the anode 11 becomes highly stable and exhibits sufficient hole injection performance. The aluminum alloy may contain silicon or copper in addition to the lanthanoid series element as a sub component. The content of the element as the sub component in the aluminum alloy is preferably 10 percent by weight or less. According to this, the anode exhibits high reflectance, high conductivity and good adhesion to the substrate 10. In addition, the high reflectance is well maintained stably and high processing accuracy and high chemical stability are obtained during manufacturing of the organic electroluminescent element.

In addition, the anode 11 may be formed to have a two-layer structure having a layer including a transparent conductive material such as ITO or IZO formed on a reflective film containing the above-mentioned metal elements (on an organic layer 20 side).

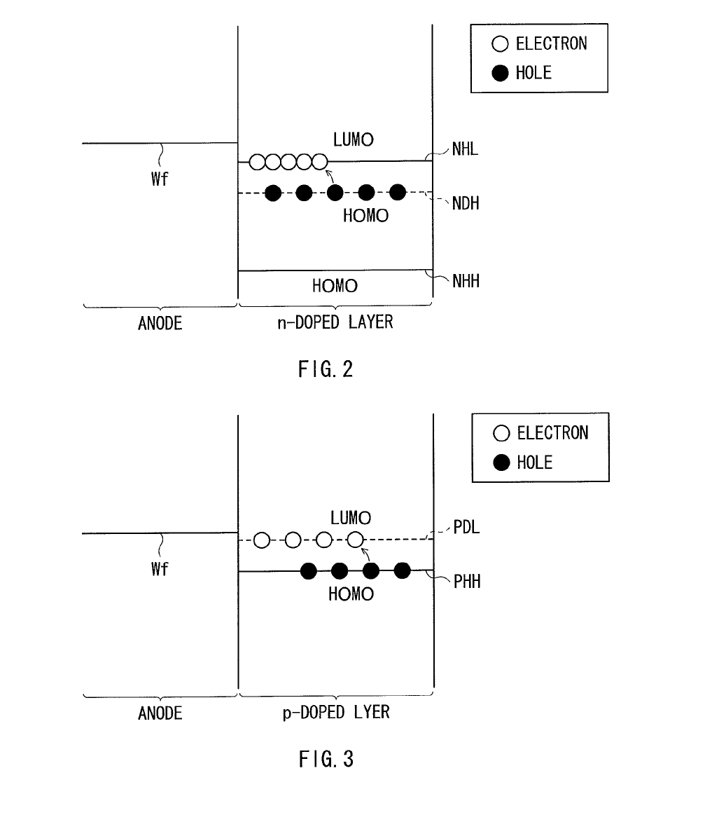

The n-doped layer 21 of the organic layer 20 injects holes efficiently into the hole transport layer 22, and includes an n-type host compound and an n-type dopant compound. Here, charge transfer in the n-doped layer 21 will be described with reference to FIGS. 2 and 3. FIG. 2 shows a relationship between a work function of the anode 11 and energy levels of HOMO and LUMO of each of a host molecule and a dopant molecule in the n-doped layer 21 in the embodiment. FIG. 3 shows a relationship between the work function of the anode and energy levels of HOMO and LUMO of each of a host molecule and a dopant molecule in a p-doped layer as a reference example for the embodiment.

As shown in FIG. 2, in the n-doped layer 21, a LUMO energy level NHL and a HOMO energy level NHH of the n-type host compound are lower than a work function Wf of the anode 11. Further, a HOMO energy level NDL of the n-type dopant compound lies between the LUMO energy level NHL and the HOMO energy level NHH of the n-type host compound. Therefore, while an electric field is not applied or is applied to the n-doped layer 21, electrons are easily extracted from HOMO (NDH) of the n-type dopant compound to LUMO (NHL) of the n-type host compound. Consequently, since the n-type dopant compound is positively charged and the n-type host compound becomes an electron path, negative space charge of the n-type host compound is relaxed. Accordingly, resistance of the n-doped layer 21 is reduced during charge transfer. In addition, electron concentration that may concern charge transfer is thus increased, and consequently charge transfer is facilitated.

In contrast, as shown in FIG. 3, in a p-doped layer, a HOMO energy level PHH of a p-type host molecule and a LUMO energy level PDL of a p-type dopant molecule are lower than the work function Wf of the anode 11. However, the LUMO energy level PDL of the p-type dopant molecule is higher than the HOMO energy level PHH of the p-type host molecule. Therefore, while an electric field is not applied or is applied to the p-doped layer, electrons are extracted from the HOMO energy level PHH of the p-type host molecule to the LUMO energy level PDL of the p-type dopant molecule. Consequently, the p-type host molecule is positively charged, and the p-type dopant molecule becomes an electron path. Accordingly, when a material having a high work function such as ITO is used for the anode, negative space charge of the p-type dopant molecule is hardly increased in the p-doped layer. However, when a material having a low work function is used for the anode, the negative space charge tends to be increased. Consequently, resistance of the p-doped layer is increased during charge transfer.

That is, when a p-doped layer is provided on the anode 11 including a material having a low work function (for example, 4.5 eV or less), drive voltage is hardly reduced, but when the n-doped layer 21 is provided thereon, drive voltage may be reduced.

Moreover, difference in absolute values between the HOMO energy (NDH) of the n-type dopant compound and the LUMO energy (NHL) of the n-type host compound is preferably 2 eV or less. According to this, electrons are more easily extracted from NDH, leading to more reduction in drive voltage.

The content (doping amount) of the n-type dopant compound in the n-doped layer 21 is preferably 2 percent by mass or more. According to this, a high voltage reduction effect is obtained compared with a case that the content is less than 2 percent by mass. In particular, the content of the n-type dopant compound in the n-doped layer 21 is preferably 2 percent by mass or more and 10 percent by mass or less. According to this, a high effect is obtained compared with a case that the content is out of the above range.

Any compound may be used as the n-type host compound as long as the compound has the relationship with the n-type dopant compound as shown in FIG. 2. In particular, a compound expressed by formula (3) (hexaazatriphenylene derivative) is preferable. By using the compound, drive voltage is reduced and hole injection efficiency is improved, and consequently high luminous efficiency is obtained.

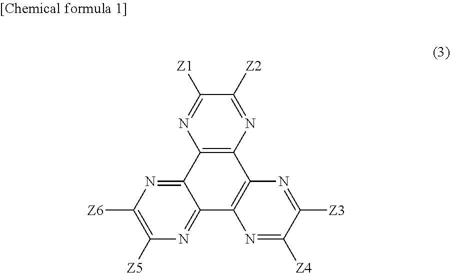

(Each of Z1 to Z6 is a hydrogen group, a halogen group, a cyano group, a nitro group, a silyl group, a hydroxyl group, an amino group, an arylamino group, a group having a carbon number of 20 or less including a carbonyl group, a group having a carbon number of 20 or less having a carbonyl ester bond, an alkyl group having a carbon number of 20 or less, an alkenyl group having a carbon number of 20 or less, an alkoxy group having a carbon number of 20 or less, a group having a carbon number of 30 or less including an aromatic ring, or a group having a carbon number of 30 or less including a hetero ring, or a derivative of each group, where Z1 and Z2, Z3 and Z4, or Z5 and Z6 may be bonded to each other to form a ring.)

Each of Z1 to Z6 in description of the formula (3) may be any one of the above groups, and adjacent groups (Z1 and Z2, Z3 and Z4, or Z5 and Z6) may be bonded to each other to form a ring. The “derivative” in the description of the formula (3) refers to a group where some or all of hydrogen atoms in an atom group to be introduced are substituted by another atom group. The same is true in formulas (1), (2), (4) and (5) described later.

As the compound expressed by the formula (3), a compound expressed by formula (3-1) is listed. That is, hexacyanoazatriphenylene of the formula (3-1) is listed. In addition, the compound of the formula (3) is not limited to the compound expressed by the formula (3-1) as long as the relevant compound has a structure expressed by the formula (3).

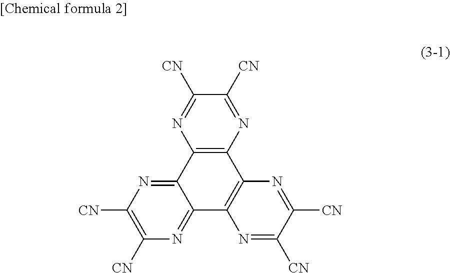

While any compound may be used as the n-type dopant compound as long as the compound has the relationship with the n-type host compound as shown in FIG. 2, one or more of amine compounds expressed by formulas (1) and (2) is preferable. By using the compound, the above effects are able to be more effectively exhibited.

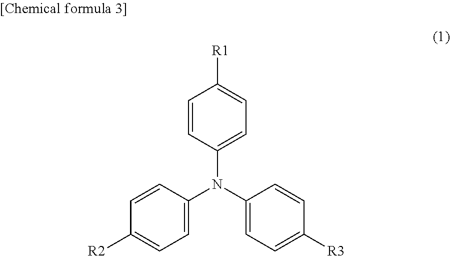

(Each of R1 to R3 is a hydrogen group, a halogen group, a hydroxyl group, an amino group, an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group.)

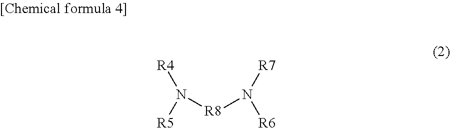

(Each of R4 to R7 is a hydrogen group, a halogen group, a hydroxyl group, an amino group, an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group, where R4 and R5, or R6 and R7 may be bonded to each other to form a ring. R8 is a monovalent or divalent group.)

Each of R1 to R3 in description of the formula (1) is any one of the above groups. The arylamino group introduced as one of R1 to R3 includes, for example, a diphenylamino group. A derivative of the arylamino group includes, for example, a carbazole group. Further, as the group having a carbon number of 20 or less including an aromatic ring, for example, the following are listed. A phenyl group, a naphthyl group, a fluorenyl group, an anthryl group, a phenanthryl group, a naphthacenyl group, a pyrenyl group, a chrysenyl group, a fluoranthenyl group, a biphenyl group, a terphenyl group, a triphenylmethyl group, a tolyl group, and a t-butylphenyl group, or derivatives of the groups.

As the amine compounds expressed by the formula (1), for example, a compound expressed by formula (1-1) is listed. That is, 4,4′,4″-tris(3-methylphenylphenylamino)triphenylamine (m-MTDATA) of the formula (1-1) is listed. The amine compound is not limited to the compound expressed by the formula (1-1) as long as the relevant compound has a structure expressed by the formula (1).

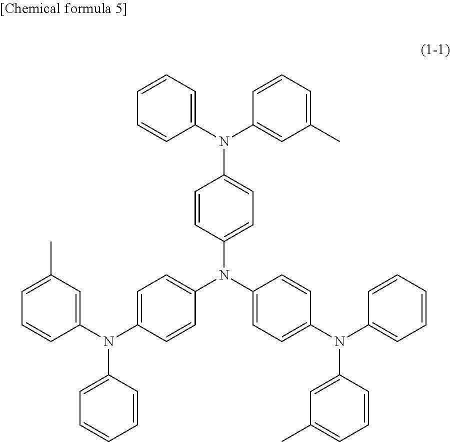

Each of R4 to R7 in description of the formula (2) is any one of the above groups, and R4 and R5 or R6 and R7 may be bonded to each other to form a ring. As the arylamino group, a derivative thereof, and the group having a carbon number of 20 or less including an aromatic ring, each group being introduced as one of R4 to R7, the same groups as those in the description of R1 to R3 are listed. R8 in description of the formula (2), which is a linking group linking between two nitrogen atoms forming an amine compound, is any one of divalent groups, but may be a monovalent group. Such a monovalent group as R8 includes, for example, the same groups as those introduced as R4 to R7.

As the amine compound expressed by the formula (2), for example, a compound expressed by formula (2-1) is listed. That is, N4,N4′-di-naphthalene-1-yl-N4,N4′-diphenyl-biphenyl-4,4′-diamine (uNPD) of the formula (2-1) is listed. The amine compound is not limited to the compound expressed by the formula (2-1) as long as the relevant amine compound has a structure expressed by the formula (2). For example, a compound, having a monovalent group as R8 and an absolute value of HOMO energy of 5.3 eV, may be used.

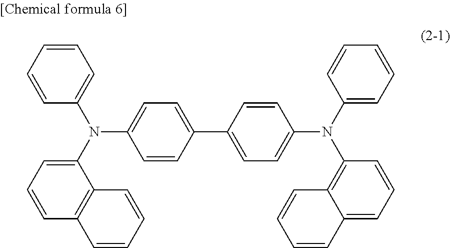

The n-type dopant compound may be a compound other than the amine compounds expressed by the formulas (1) and (2), and may include, for example, amine compounds expressed by formula (4) or (5).

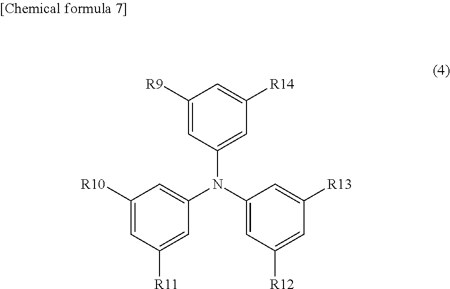

(Each of R9 to R14 is a hydrogen group, a halogen group, a hydroxyl group, an amino group, an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group.)

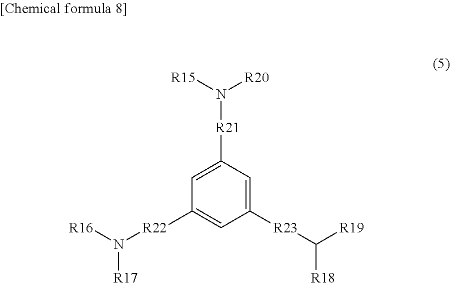

(Each of R15 to R20 is a hydrogen group, a halogen group, a hydroxyl group, an amino group, an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group, where R15 and R20, R16 and R17, or R18 and R19 may be bonded to each other to form a ring. Each of R21 to R23 is a divalent group.)

The hole transport layer 22 is for efficiently transporting holes injected form the n-doped layer 21 to the light emission layer 23. Any material may be used as a material forming the hole transport layer 22 as long as the material may efficiently transport holes. For example, the following materials are listed. The materials may be singly used, or may be used in a mixed manner.

Benzine, styrylamine, triphenylamine, porphyrin, triphenylene, azatriphenylene, tetracyanoquinodimethane, triazole, oxadiazole, polyaryl alkane, phenylenediamine, arylamine, oxazole, anthracene, fluorenone, hydrazone, and stilbene, or derivatives of them. A monomer, an oligomer, or a polymer of a heterocyclic conjugated system such as a polysilane compound, a vinylcarbazole compound, a thiophene compound, or an aniline compound.

Specifically, the following compounds are listed.

4,4′,4″-Tris(3-methylphenylphenylamino)triphenylamine (m-MTDATA; the compound expressed by the formula (2-1)), α-naphthylphenylphenylendiamine, porphyrin, metallotetraphenylporphyrin, metallonaphtalocyanine. Hexacyanoazatriphenylene (the compound expressed by the formula (3-1)), 7,7,8,8-tetracyanoquinodimethane (TCNQ), 2,3,5,6-tetra-fluoro-7,7,8,8-tetracyanoquinodimethane (F4-TCNQ) expressed by formula (6), tetracyano-4,4,4-tris(3-methylphenylphenylamino)triphenylamine, N,N,N′,N′-tetrakis(p-tolyl)ₚ-phenylenediamine, N,N,N′,N′-tetraphenyl-4,4′-diaminobiphenyl, and N-phenylcarbazole. 4-di-p-tolylaminostilbene, poly(paraphenylenevinylene), poly(thiophenevinylene), and poly(2,2′-thienylpyrrole).

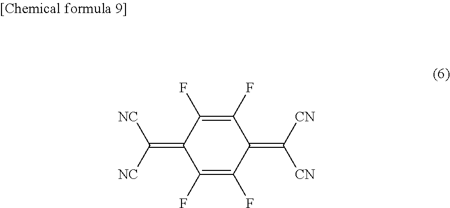

The light emitting layer 23 corresponds to a region where when an electric field is applied between the anode 11 and the cathode 31, holes injected from an anode 11 side are recombined with electrons injected from a cathode 31 side, leading to light emission. A material forming the light emitting layer 23 preferably has light emission capability (capability of providing a recombination site for holes and electrons, and leading such recombination to light emission), and has, for example, charge injection capability and charge transport capability. This improves luminous efficiency, and besides enables light emission even if the hole transport layer 22, the electron transport layer 24, or a first layer 31A of the cathode 31 is not provided. The charge injection capability mentioned herein means a capability of allowing holes to be injected from the n-doped layer 21 and allowing electrons to be injected from the cathode 31 during application of an electric field. The charge transport capability means a capability of allowing the injected holes and electrons to be transferred by force of an electric field.

As a material forming the light emitting layer 23, for example, the following are listed.

Naphthalene derivatives, indene derivatives, phenanthrene derivatives, pyrene derivatives, naphthacene derivatives, triphenylene derivatives, anthracene derivatives, perylene derivatives, picene derivatives, fluoranthene derivatives, acephenanthrylene derivatives, pentaphene derivatives, pentacene derivatives, coronene derivatives, butadiene derivatives, stilbene derivatives, tris(8-quinolinolato)aluminum complex (Alq), or bis(benzoquinolinolato)beryllium complex. Specifically, uNPD as the compound expressed by the formula (1-1) is listed.

Moreover, in the light emitting layer 23, for example, luminescent dyes (light-emitting guest materials) of respective colors (blue, green and red) may be doped into a compound as a host (host material). In this case, when an electric field is applied, each color light is emitted in accordance with a color of the relevant luminescent dye.

A material forming the host material includes, for example, the materials forming the light emitting layer 23. That is, the material includes the following materials.

Naphthalene derivatives, indene derivatives, phenanthrene derivatives, pyrene derivatives, naphthacene derivatives, triphenylene derivatives, anthracene derivatives, perylene derivatives, picene derivatives, fluoranthene derivatives, acephenanthrylene derivatives, pentaphene derivatives, pentacene derivatives, coronene derivatives, butadiene derivatives, stilbene derivatives, tris(8-quinolinolato)aluminum complex (Alq), or bis(benzoquinolinolato)beryllium complex.

Specifically, for example, 9,10-di(2-naphthyl)anthracene (AND) or the like is listed.

As the light-emitting guest materials, materials having high luminous efficiency, for example, organic light-emitting materials such as low-molecular fluorescent dyes, fluorescent polymers, and metal complexes are used. Hereinafter, a light-emitting guest material of each of colors will be described.

A blue light-emitting guest material means a compound with an emission wavelength range having a peak within a range of approximately 400 nm to 490 nm. Such an organic compound includes the following. Naphthalene derivatives, anthracene derivatives, naphthacene derivatives, styrylamine derivatives, or bis(azinyl)methane boron complex are listed. Specifically, aminonaphthalene derivatives, aminoanthracene derivatives, aminochrysene derivatives, aminopyrene derivatives, styrylamine derivatives, or bis(azinyl)methane boron complex are listed. The materials may be singly used, or may be used in a mixed manner.

A green light-emitting guest material means a compound with an emission wavelength range having a peak within a range of approximately 490 nm to 580 nm. Such an organic compound includes the following. Naphthalene derivatives, anthracene derivatives, pyrene derivatives, naphthacene derivatives, fluoranthene derivatives, perylene derivatives, coumalin derivatives, quinacridone derivatives, indeno[1,2,3-cd]perylene derivatives, or bis(azinyl)methane boron complex pyran-based dyes. Specifically, aminoanthracene derivatives, fluoranthene derivatives, coumalin derivatives, quinacridone derivatives, indeno[1,2,3-cd]perylene derivatives, and bis(azinyl)methane boron complex are listed. The materials may be singly used, or may be used in a mixed manner.

A red light-emitting guest material means a compound with an emission wavelength range having a peak within a range of approximately 580 nm to 700 nm. Such an organic compound includes the following. Nile Red, pyran derivatives such as DCM1 ({4-Dicyanmethylene-2-methyl-6(p-dimethylamino styryl)-4H-pyran}) or DCJT ({4-Dicyanomethylene-2-t-butyl-6-(julolidylstyryl)-pyran}, sqarylium derivatives, porphyrin derivatives, chlorin derivatives, and eurodiline derivatives. The materials may be singly used, or may be used in a mixed manner.

In the light emitting layer 23, the light-emitting guest materials of the respective colors may be used such that one color light is emitted, or may be used such that light emitting layers, each emitting one color light, are stacked to obtain white emission light. That is, the light emitting layer 23 may be one of a blue emitting layer, a green emitting layer and a red emitting layer, or may be a white emitting layer with the layers being stacked.

The electron transport layer 24 is for efficiently transporting electrons injected form the cathode 31 to the light emission layer 23. A material forming the electron transport layer 24 includes, for example, the following materials. Quinolone, perylene, phenanthroline, bistyryl, pyrazine, triazole, oxazole, oxadiazole, and fluorenone, or derivatives of the materials, or metal complexes thereof. Specifically, the following compounds are listed. Tris(8-hydroxyquinolin)aluminum (Alq3), anthracene, naphthalene, phenanthrene, pyrene, anthracene, perylene, butadiene, coumalin, acridine, stilbene, and 1,10-phenanthroline, or derivatives of the materials, or metal complexes thereof. The materials may be singly used, or may be used in a mixed manner.

The cathode 31 is one electrode for applying an electric field to the light emission layer 23, and is formed of a light-transmitting material. According to this, emission light from the light emission layer 23 and reflected light of the emission light on a surface of the anode 11 are extracted to the outside from the cathode 31. In the cathode 31, a layer using a material having a low work function is formed on a light emission layer 23 side, and the first layer 31A and a second layer 31B are stacked in order from the light emission layer 23 side.

The first layer 31A is formed of a material that has a high light-transmitting property and a low work function and may efficiently inject electrons into the electron transport layer 24. That is, the first layer 31A serves as an electron injection layer. Such a material includes, for example, alkali metal oxide, alkali metal fluoride, alkali-earth metal oxide, or alkali-earth fluoride such as Li₂O, Cs₂O, LiF or CaF₂.

Further, the second layer 31B is formed of a material that has a light-transmitting property and good conductivity such as a thin-film electrode material of MgAg or Ca. Moreover, when the organic electroluminescent element has a cavity structure where emission light is extracted while being resonated between the anode 11 and the cathode 31, the second layer 31B may be formed of a semi-transmissive reflective material such as Mg—Ag (9:1) 10 nm thick.

In addition, the cathode 31 may have a structure where a third layer (not shown) is stacked as a seal electrode on the second layer 31B for suppressing degradation of the electrode as necessary.

Such an organic electroluminescent element may be manufactured, for example, in the following way.

First, the anode 11 is formed on a substrate by an evaporation method or a sputtering method. Next, the n-doped layer 21, the hole transport layer 22, the light emitting layer 23 and the electron transport layer 24 are stacked in this order by a vacuum evaporation method or the like so that the organic layer 20 is formed. Finally, the first layer 31A and the second layer 31B are stacked in this order by a vacuum evaporation method or the like so that the cathode 31 is formed. In this way, the organic electroluminescent element shown in FIG. 1 is completed.

In the organic electroluminescent element of the embodiment, when voltage is applied between the anode 11 and the cathode 31 and thus an electric field is applied to the organic layer 20, holes from the anode 11 are efficiently transferred to the light emitting layer 23 via the n-doped layer 21 and the hole transport layer 22. On the other hand, electrons from the cathode 31 are efficiently transported to the light emitting layer 23 via the electron transport layer 24. In this way, holes transferred from an anode 11 side and electrons transferred from a cathode 31 side are recombined in the light emitting layer 23, leading to light emission. Such emission light from the light emission layer 23 and reflected light of the emission light on a surface of the anode 11 transmit through the cathode 31 and are outputted. Here, in the n-doped layer 21, electrons are easily extracted from HOMO (NDH) of the n-type dopant compound to LUMO (NHL) of the n-type host compound as shown in FIG. 2. Accordingly, since the n-type dopant compound is positively charged and the n-type host compound becomes an electron path, negative space charge of the n-type host compound is relaxed, and thus resistance of the n-doped layer 21 is reduced during charge transfer. In addition, concentration of electrons that may concern charge transfer is increased, and consequently charge transfer is generally facilitated.

That is, in the organic electroluminescent element, since the n-doped layer 21 is provided between the anode 11 and the light emission layer 23, drive voltage may be reduced, and luminous efficiency may be thus improved. In this case, when the content of the n-type dopant compound in the n-doped layer 21 is 2 percent by mass or more, drive voltage may be more reduced.

When the anode 11 contains aluminum, high effects may be obtained compared with a case where the anode includes a material having a high work function.

Next, an application example of the organic electroluminescent element will be described. To give an instance of a display device, the organic electroluminescent element is used in the following manner.

### [(1-2) Display Device]

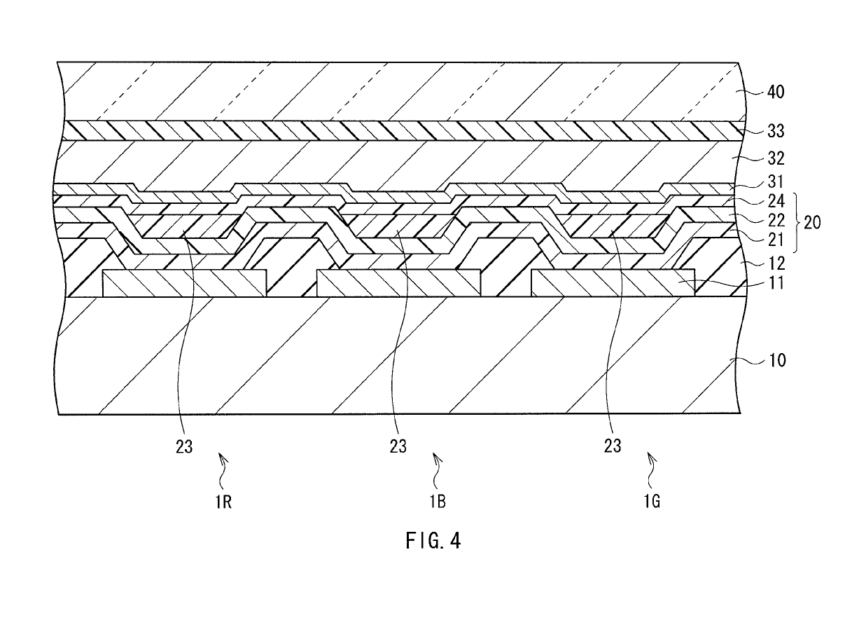

FIG. 4 shows a sectional configuration of a display device. The display device has a configuration where an insulating layer 12 and organic electroluminescent elements 1R, 1G and 1B are provided on a drive substrate 10 having driver circuits (not shown) such as TFT. In the display device, a protective layer 32 is formed on the organic electroluminescent elements 1R, 1G and 1B so as to cover the elements, and a sealing substrate 40 is adhered on the protective layer 32 by an adhesion layer 33 provided on the protective layer 32 so as to seal the display device over the whole area. That is, the display device described herein is driven by an active matrix method.

The drive substrate 10 is designed such that the driver circuits (not shown) such as TFT for each of the organic electroluminescent elements 1R, 1G and 1B and a planarization insulating film (not shown) are provided on a transparent substrate such as a glass substrate, a silicon substrate, or a film-shaped flexible substrate.

The organic electroluminescent element 1R, 1G or 1B has the same configuration as that of the aforementioned organic electroluminescent element. In the display device, light extracted from the organic electroluminescent elements 1R, 1G and 1B are assumed to have colors of red, green and blue, respectively. In addition, since the sealing substrate 40 described later has a color filter (not shown), light emitting layers 23 of the organic electroluminescent elements 1R, 1G and 1B have the same configuration herein. However, the light emitting layers 23 may have different configurations, respectively. In such a case, the light emitting layers 23 of the organic electroluminescent elements 1R, 1G and 1B include different light-emitting guest materials.

The insulating layer 12 is for ensuring insulation between the anode 11 and the cathode 31 of each of the organic electroluminescent elements 1R, 1G and 1B, and accurately adjusting each light emitting region to be a desired shape. The insulating layer 12 is provided, on the substrate 10, between the anodes 11 of the organic electroluminescent elements 1R, 1G and 1B in a manner of surrounding each anode 11 to form openings. Such an insulating layer 12 is formed of, for example, photosensitive resin such as polyimide. In addition, while the organic layer 20 and the cathodes 31 are successively formed even on the insulating layer 12 herein, emission light is generated only in each opening of the insulating layer 12 (above the anode 11).

The protective layer 32 is for preventing entering of water into the organic layer 20, and is formed of a material having low water-permeable and low water-absorbing properties and has sufficient thickness. In addition, the protective layer 32 is formed of a material having a high transmitting property to light generated by the light emitting layer 23, and having a transmittance of, for example, 80% or more. For example, such a protective layer 32 has a thickness of approximately 2 μm to 3 μm, and is formed of an amorphous insulating material. Specifically, the protective layer is preferably formed of amorphous silicon (α-Si), amorphous silicon carbide (α-SiC), amorphous silicon nitride (α-Si₁₋ₓNₓ), or amorphous carbon (α-C). The amorphous insulating materials do not form grains and therefore have a low water-absorbing property, leading to a good protective layer 32. The protective layer 32 may be formed of a transparent conductive material such as ITO.

The adhesion layer 33 is formed of, for example, thermosetting resin or (UV) ultraviolet curing resin.

The sealing substrate 40, which is located on a cathode 31 side with respect to the organic electroluminescent elements 1R, 1G and 1B, seals the organic electroluminescent elements 1R, 1G and 1B in conjunction with the adhesion layer 32. The sealing substrate 40 is formed of a material such as glass that may transmit light generated by the organic electroluminescent element 1R, 1G or 1B. For example, a color filter (not shown) is provided on the sealing substrate 40. This enables a design that while light generated by the organic electroluminescent element 1R, 1G or 1B is extracted, outside light, which is reflected by the organic electroluminescent elements 1R, 1G and 1B and wirings (not shown) between the organic electroluminescent element 1R, 1G or 1B, is absorbed, so that contrast may be improved.

While the color filter may be provided on a surface on either side of the sealing substrate 40, the color filter is preferably provided on an organic electroluminescent elements 1R, 1G and 1B side. According to this, the color filter may be prevented from being exposed to a surface and thus may be protected by the adhesion layer 33. In addition, a distance between the light emitting layer 23 and the color filter is reduced, which may avoid a phenomenon that light emitted from the organic electroluminescent element 1R, 1G or 1B enters into an adjacent color filter of a different color and thus causes color mixing. The color filter includes red filters, green filters and blue filters (any of them is not shown), which are arranged in order in correspondence to the organic electroluminescent elements 1R, 1G and 1B. The red filters, the green filters and the blue filters are formed, for example, in a rectangular shape with no gap, respectively. The red filters, the green filters and the blue filters may be formed of resin mixed with pigments, respectively. The pigment is selected so that light transmittance is adjusted to be high in a target wavelength range of red, green or blue and low in other wavelength ranges.

The display device may be manufactured, for example, in the following way.

First, the drive substrate 10 is prepared, and the anode 11 is formed on the drive substrate 10 by, for example, a sputtering method, and the anode 11 is formed into a predetermined shape by, for example, dry etching.

Next, photosensitive resin is coated over the whole area on the substrate 10 so as to cover the anode 11, and openings are provided in correspondence to light emitting regions by, for example, a photolithography method, and then the photosensitive resin is fired, so that the insulating layer 12 is formed.

After that, an organic layer 20 is formed according to, for example, the same procedure as in manufacturing of the organic electroluminescent element, and then a cathode 31 is formed on the organic layer 20. In this way, organic electroluminescent elements 1R, 1G and 1B are formed.

After the organic electroluminescent elements 1R, 1G and 1B are formed, the protective film 32 is formed thereon. As a method of forming the protective film 32, a deposition method such as an evaporation method or a CVD method, in which energy of each deposition particle is small enough to avoid affecting an under layer, is preferably listed. Moreover, the protective film 32 is desirably successively formed after formation of the cathode 31 without exposing the cathode 31 to the atmosphere. According to this, the organic layer 20 may be prevented from being degraded due to water or oxygen in the atmosphere. Furthermore, deposition temperature of the protective film 32 is desirably set to normal temperature in order to prevent reduction in luminance due to degradation of the organic layer 20, and the protective film 32 is desirably deposited at a minimum film-stress condition in order to prevent separation of the film.

Moreover, for example, a material of red filters is coated on the sealing substrate 40 by spin coating or the like, and the coated material is patterned by a photolithography technique and then fired so that the red filters are formed. Subsequently, blue filters and green filters are sequentially formed in the same way as in the red filter.

Then, the adhesion layer 33 is formed on the protective film 32, and the sealing substrate 40 is attached on the protective film 32 with the adhesion layer 33 in between. At this time, a surface of the sealing substrate 40, having the color filter formed thereon, is preferably disposed on an organic electroluminescent elements 1R, 1G and 1B side. In this way, the display device shown in FIG. 4 is completed.

In such a display device, when drive voltage is applied between the anode 11 and the cathode 31 of each of the organic electroluminescent elements 1R, 1G and 1B selected based on image data, an electric field is applied to the organic layer 20. When the organic layer 20 is applied with the electric field, holes are recombined with electrons in the light emitting layer 23, leading to generation of emission light. The emission light is extracted through the color filter and the sealing substrate 40.

According to the display device, since the organic layer 20 of each of the organic electroluminescent elements 1R, 1G and 1B has the n-doped layer 21 between the anode 11 and the light emitting layer 23, drive voltage may be reduced. Other operation and effects are the same as in the organic electroluminescent element.

In addition, while the organic layer 20 is configured of the n-doped layer 21, the hole transport layer 22, the light emitting layer 23 and the electron transport layer 24 in the embodiment, this is not limitative. That is, the organic layer 20 only needs to have the n-doped layer 21 between the light emitting layer 23 and the anode 11, and may have other layers as necessary. The same is true in a configuration of the cathode 31.

Furthermore, while the embodiment has been mainly described on a case where each of the n-doped layer 21, the hole transport layer 22, the light emitting layer 23 and the electron transport layer 24, the layers forming the organic layer 20, is formed as a single layer, each layer may be formed as a multilayer. Even in such a case, the same operation and effects may be obtained.

### 2. Second Embodiment (Wiring Material)

A wiring material according to a second embodiment of the invention is used for a circuit board mounted in a display device or the like, and is an n-doped, organic conductive material including the n-type host material and the n-type dopant material. According to this, current application may be performed at low voltage.

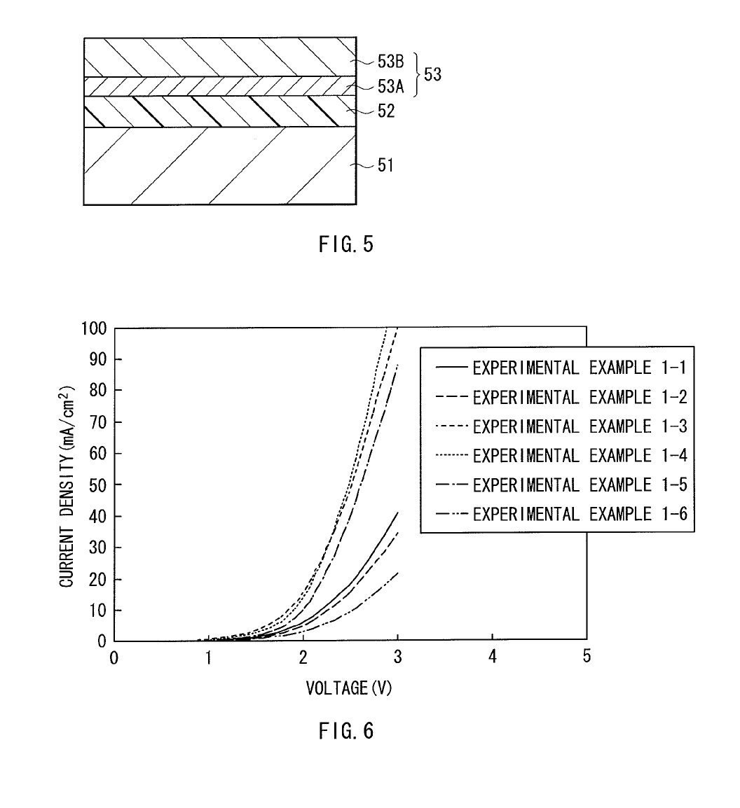

For example, the wiring material may be used for a wiring structure shown in FIG. 5. FIG. 5 schematically shows a wiring structure using the wiring material. The wiring structure has an n-doped layer 52 as a layer including the wiring material between a first electrode 51 (for example, anode) and a second electrode 53 (for example, cathode).

For example, the first electrode 51 has the same configuration as the anode 11 of the organic electroluminescent element. Moreover, the n-doped layer 52 is formed of a wiring material including the n-type host material and the n-type dopant material, and thus has the same configuration as the n-doped layer 21. The second electrode 53 has a structure where the first layer 53A and the second layer 53B are stacked from the n-doped layer 52 side, and, for example, has the same configuration as the cathode 31 (first layer 31A and second layer 32B). In addition, while the second electrode 53 may have a light-transmitting property as in the cathode 31, the electrode 53 may be formed of a non-light-transmitting material, for example, the same material as that of the first electrode 51.

For example, the wiring structure may be manufactured by stacking the first electrode 51, the n-doped layer 52, and the second electrode 53 on a substrate by an evaporation method or the like.

In the wiring structure, while an electric field is not applied or is applied between the electrodes, electrons are easily extracted from HOMO (NDH) of the n-type dopant compound to LUMO (NHL) of the n-type host compound in the n-doped layer 52, as shown in FIG. 2. Accordingly, since the n-type dopant compound is positively charged and the n-type host compound becomes an electron path, negative space charge of the n-type host compound is relaxed, and resistance of the n-doped layer 52 is reduced during charge transfer. In addition, concentration of electrons that may concern charge transfer is increased, which facilitates charge transfer. That is, according to the wiring structure, current application may be performed at low voltage compared with a case of using an organic material other than the material forming the n-doped layer 52. Consequently, according to the wiring material, a low-resistance organic-compound wiring may be achieved without using a metal material or the like.

### EXAMPLES

Examples of the invention will be described in detail.

### Experimental Examples 1-1 to 1-5

A wiring structure shown in FIG. 5 was produced according to the following procedure.

First, the first electrode 51 (Al) including aluminum 200 nm in thickness was formed on a glass substrate by RF magnetron sputtering. Next, the substrate formed with the first electrode 51 was carried into a plasma apparatus, and subjected to oxygen plasma (80 W and 10 Pa) treatment for 3 minutes under a vacuum atmosphere to clean a surface of the substrate. Next, the cleaned substrate was carried into an evaporation apparatus and the n-doped layer 52 of 100 nm in thickness was formed in a vacuum atmosphere in the apparatus. Here, the compound (HAT) expressed by the formula (3-1) was used as the n-type host compound and the compound (uNPD) expressed by the formula (2-1) was used as the n-type dopant compound, and the compounds were co-evaporated while the content of the n-type dopant compound was adjusted to obtain a composition shown in Table 1. Specifically, the content of the n-type dopant compound in the n-doped layer 52 was adjusted to be 0.5 percent by mass (experimental example 1-1), 1 percent by mass (experimental example 1-2), 2 percent by mass (experimental example 1-3), 4 percent by mass (experimental example 1-4) or 10 percent by mass (experimental example 1-5). Next, lithium fluoride (LiF) was vacuum-evaporated with a thickness of 0.3 nm as the first layer 53A of the second electrode 53, and magnesium-silver alloy (MgAg, 10:1 in mass ratio) was co-evaporated as the second layer 53B on the first layer 53A with a thickness of 10 nm. Next, the substrate was carried into a plasma CVD apparatus, and a silicon nitride film (1 μm thick) was formed on the second layer 53B in the apparatus. Finally, UV curing resin was dropped onto the silicon nitride film, and a glass substrate was attached thereon for sealing. In this way, the wiring structure shown in FIG. 5 was completed.

### Experimental Example 1-6

A wiring structure was produced through the same procedure as in the experimental example 1-1 except that a layer including the compound (HAT) expressed by the formula (3-1) was formed in place of the n-doped layer 52 by vacuum evaporation with a thickness of 100 nm.

TABLE 1

| | | N-doped layer | | | | |
|---|---|---|---|---|---|---|
| | | | N-type dopant | | | |
| | | | compound | | Second electrode | |
| | First | N-type host | | Doping amount | | Second |
| | electrode | compound | Type | (percent by mass) | First layer | layer |
| Experimental | Al | Formula | Formula | 0.5 | LiF | MgAg |
| example 1-1 | | (3-1) | (2-1) | | | |
| Experimental | | HAT | αNPD | 1.0 | | |
| example 1-2 | | | | | | |
| Experimental | | | | 2.0 | | |
| example 1-3 | | | | | | |
| Experimental | | | | 4.0 | | |
| example 1-4 | | | | | | |
| Experimental | | | | 10.0 | | |
| example 1-5 | | | | | | |
| Experimental | Al | Formula | — | — | LiF | MgAg |
| example 1-6 | | (3-1) | | | | |
| | | HAT | | | | |

A voltage up to 3 V was applied between the electrodes of each of the wiring structures of the experimental examples 1-1 to 1-6 so that current density was measured. As a result, results as shown in FIG. 6 were obtained.

As shown in FIG. 6, current density was extremely high in the experimental examples 1-1 to 1-5, in which the n-doped layer 52 was formed between the electrodes, compared with the experimental example 1-6, in which the n-doped layer 52 was not formed. Moreover, current density was extremely high in the experimental examples 1-3 to 1-5, in which the content of the n-type dopant compound in the n-doped layer 52 was 2 percent by mass or more, compared with the experimental examples 1-1 and 1-2, in which the content is less than 2 percent by mass. These revealed that current was able to be applied at lower voltage by using a wiring material containing the n-type host compound and the n-type dopant compound forming the n-doped layer 52. Furthermore, it was revealed that when the content of the n-type dopant compound in the wiring material was 2 percent by mass or more, current was able to be applied at further lower voltage.

### Experimental Example 2-1

An organic electroluminescent element shown in FIG. 1 was produced according to the following procedure.

First, the anode 11 including aluminum (Al) of 200 nm in thickness was formed on a glass substrate by RF magnetron sputtering. Next, the substrate formed with the anode 11 was carried into a plasma apparatus, and subjected to oxygen plasma (80 W and 10 Pa) treatment for 3 minutes in a vacuum atmosphere to clean a surface of the substrate. Next, the cleaned substrate was carried into an evaporation apparatus and the organic layer 20 was formed in a vacuum atmosphere in the apparatus. Here, first, the n-doped layer 21 (20 nm thick) was formed on the anode 11 by co-evaporation with the content of the n-type dopant compound being adjusted to be 4 percent by mass. At that time, the compound (HAT) expressed by the formula (3-1) was used as the n-type host compound, and the compound (m-MTDATA) expressed by the formula (1-1) was used as the n-type dopant. Then, the hole transport layer 22 (20 nm thick) including m-MTDATA, the light emitting layer 23 (20 nm thick) including uNPD and the electron hole transport layer 24 including Alq were evaporated, respectively. Next, lithium fluoride (LiF) was vacuum-evaporated with a thickness of 0.3 nm as the first layer 31A of the cathode 31, and magnesium-silver alloy (MgAg, 10:1 in mass ratio) was co-evaporated as the second layer 31B on the first layer 31A with a thickness of 10 nm. Next, the substrate was carried into a plasma CVD apparatus, and a silicon nitride film (1 μm thick) was formed on the second layer 31B in the apparatus. Finally, UV curing resin was dropped onto the silicon nitride film, and a glass substrate was attached thereon for sealing. In this way, the organic electroluminescent element shown in FIG. 1 was completed. Table 2 shows absolute values (eV) of energy of HOMO and LUMO of each of the n-type host compound and the n-type dopant compound in the n-doped layer 21 used herein.

### Experimental Example 2-2

An organic electroluminescent element was produced through the same procedure as in the experimental example 2-1 except that when the n-doped layer 21 is formed, uNPD (formula (2-1)) was used as the n-type dopant compound in place of m-MTDATA (formula (1-1)).

### Experimental Example 2-3

An organic electroluminescent element was produced through the same procedure as in the experimental example 2-1 except that a layer including the compound expressed by the formula (3-1) was formed in place of the n-doped layer 21 by vacuum evaporation with a thickness of 20 nm.

### Experimental Example 2-4

An organic electroluminescent element was produced through the same procedure as in the experimental example 2-1 except that a layer (20 nm thick) including the compound expressed by the formula (3-1) and F4-TCNQ as the compound expressed by the formula (6) was formed in place of the n-doped layer 21. Here, the layer was formed by co-evaporation such that the content of F4-TCNQ was 4 percent by volume.

Drive voltage and luminous efficiency of each of the organic electroluminescent elements of the experimental examples 2-1 to 2-4 were measured at a current density of 100 mA/cm². As a result, results as shown in Table 3 were obtained.

TABLE 2

| | HOMO (eV) | LUMO (eV) |
|---|---|---|
| Formula (3-1); HAT | 7.0 | 4.4 |
| Formula (1-1); m-MTDATA | 5.1 | — |
| Formula (2-1); αNPD | 5.4 | — |
| Formula (6); F4-TCNQ | 8.3 | 5.2 |

TABLE 3

| | | Organic layer | | | | | | | | |
|---|---|---|---|---|---|---|---|---|---|---|
| | | | | Hole | Light | Electron | Cathode | | Drive | Luminous |
| | | N-doped layer | | transport | emitting | transport | First | Second | voltage | efficiency |
| | Anode | Host | Dopant | layer | layer | layer | layer | layer | (V) | (cd/A) |
| Experimental | Al | Formula | Formula | Formula | Formula | Alq | LiF | MgAg | 6.9 | 6.3 |
| example 2-1 | | (3-1) | (1-1) | (1-1) | (2-1) | | | | | |
| | | HAT | m-MTD | m-MTD | αNPD | | | | | |
| | | | ATA | ATA | | | | | | |
| Experimental | | | Formula | | | | | | 7.0 | 6.3 |
| example 2-2 | | | (2-1) | | | | | | | |
| | | | αNPD | | | | | | | |
| Experimental | Al | Formula | — | Formula | Formula | Alq | LiF | MgAg | 7.5 | 6.0 |
| example 2-3 | | (3-1) | | (1-1) | (2-1) | | | | | |
| | | HAT | | m-MTD | αNPD | | | | | |
| Experimental | | Formula | Formula | ATA | | | | | 7.4 | 6.1 |
| example 2-4 | | (3-1) | (6) | | | | | | | |
| | | HAT | F4-TCNQ | | | | | | | |

As shown in Table 3, drive voltage was low and thus luminous efficiency was high in the experimental examples 2-1 and 2-2, in which the n-doped layer 21 was formed, compared with the experimental examples 2-3 and 2-4, in which the n-doped layer 21 was not formed. In this case, as shown in Table 1, difference in absolute value between HOMO energy of m-MTDATA or uNPD (n-type dopant compound) and the compound expressed by the formula (3-1) (n-type host compound) was 2 eV or less. When F4-TCNQ as a so-called p-type dopant compound was used in place of the n-type dopant compound, the effect of reduction in drive voltage was not obtained.

This revealed that the organic electroluminescent element had the n-doped layer 21 between the anode 11 and the light emitting layer 23, so that drive voltage was able to be reduced and thus luminous efficiency was improved. Here, the results of the experimental examples 1-1 to 1-5 suggest that when the content of the n-type dopant compound in the n-doped layer 21 is 2 percent by mass or more, drive voltage may be more reduced.

While the invention has been described with the embodiments and the examples, the invention is not limited to the aspects described in the embodiments and the examples hereinbefore, and various modifications or alterations may be made. For example, while the embodiments and the examples have been described on a top-emission-type organic electroluminescent element, a bottom-emission-type organic electroluminescent element may be used. In such a case, a field emission element has a structure where the cathode, the organic layer and the anode are stacked in order on a substrate formed of a transparent material, and the organic layer has a structure where the electron transport layer, the light emitting layer and the hole transport layer are stacked in order from a cathode side.

While the embodiments have been described on an active-matrix display device, a passive display device may be used.

1. An organic electroluminescent element comprising:
an organic layer including a light emitting layer between an anode and a cathode,
wherein the organic layer has an n-doped layer, including an n-type host compound and an n-type dopant compound, between the anode and the light emitting layer.

2. The organic electroluminescent element according to claim 1,
wherein the content of the n-type dopant compound in the n-doped layer is 2 percent by mass or more.

3. The organic electroluminescent element according to claim 1,
wherein the anode contains aluminum as a constituent element.

4. The organic electroluminescent element according to claim 1,
wherein the organic layer has a hole transport layer between the n-doped layer and the light emitting layer.

5. The organic electroluminescent element according to claim 1,
wherein the n-type dopant compound is one or more of amine compounds expressed by formulas (1) and (2): 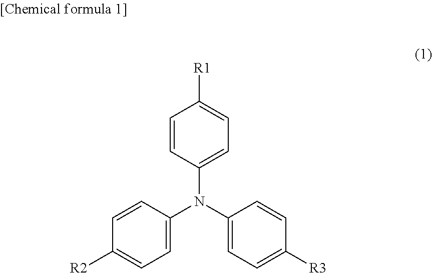
(each of R1 to R3 is a hydrogen group, a halogen group, a hydroxyl group, an amino group, an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group); 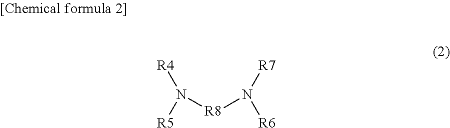
(each of R4 to R7 is a hydrogen group; a halogen group, a hydroxyl group, an amino group; an arylamino group having a carbon number of 20 or less, a group having a carbon number of 20 or less including a carbonyl group, a group having a carbon number of 20 or less including a carbonyl ester bond, an alkyl group having a carbon number of 20 or less, an alkenyl group having a carbon number of 20 or less, an alkoxy group having a carbon number of 20 or less, or a group having a carbon number of 20 or less including an aromatic ring, or a derivative of each group, where R4 and R5, or R6 and R7 may be bonded to each other to form a ring, and R8 is a divalent group.)

6. The organic electroluminescent element according to claim 1,
wherein the n-type host compound is a compound expressed by formula (3): 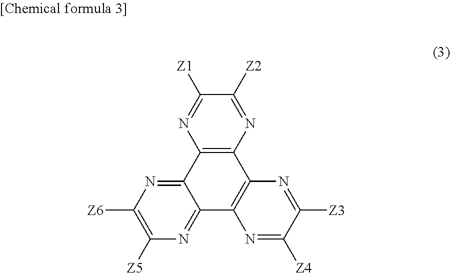
(each of Z1 to Z6 is a hydrogen group, a halogen group, a cyano group, a nitro group, a silyl group, a hydroxyl group, an amino group, an arylamino group, a group having a carbon number of 20 or less including a carbonyl group, a group having a carbon number of 20 or less having a carbonyl ester bond, an alkyl group having a carbon number of 20 or less, an alkenyl group having a carbon number of 20 or less, an alkoxy group having a carbon number of 20 or less, a group having a carbon number of 30 or less including an aromatic ring, or a group having a carbon number of 30 or less including a hetero ring, or a derivative of each group, where Z1 and Z2, Z3 and Z4, or Z5 and Z6 may be bonded to each other to form a ring.)

7. The organic electroluminescent element according to claim 1,
wherein difference in absolute value between highest occupied molecular orbital (HOMO) energy of the n-type dopant compound and lowest unoccupied molecular orbital (LUMO) energy of the n-type host compound is 2 eV or less.

8. The organic electroluminescent element according to claim 1,
wherein the anode has a light reflectivity, and the cathode has a light permeability, and
light emitted from the light emitting layer is outputted from a cathode side.

9. A display device comprising:
an organic electroluminescent element having an organic layer including a light emitting layer between an anode and a cathode,
wherein the organic layer has an n-doped layer, including an n-type host compound and an n-type dopant compound, between the anode and the light emitting layer.
